(19) United States
(12) Patent Application Publication
(10) Pub. No.: US 2026/0090235 A1
(43) Pub. Date: Mar. 26, 2026

(54) DISPLAY PANEL, ELECTRONIC APPARATUS INCLUDING THE SAME AND METHOD OF MANUFACTURING DISPLAY PANEL

(71) Applicant: Samsung Display Co., Ltd., Yongin-si (KR)

(72) Inventors: HANBIT KIM, Yongin-si (KR); MEEJAE KANG, Yongin-si (KR); JIYEONG SHIN, Yongin-si (KR); DOKYEONG LEE, Yongin-si (KR); KISEOK CHOI, Yongin-si (KR); SANGGUN CHOI, Yongin-si (KR)

(21) Appl. No.: 19/231,348

(22) Filed: Jun. 6, 2025

(30) Foreign Application Priority Data
Sep. 24, 2024 (KR) 10-2024-0128709

(51) Int. Cl. H10K 59/80; H10K 59/12; H10K 59/35

(52) U.S. Cl. CPC H10K 59/80518; H10K 59/1201; H10K 59/353; H10K 59/80517

(57) ABSTRACT

A display panel includes first and second light-emitting elements including a first electrode including a reflection layer and a metal oxide layer, an emission unit configured to generate first, second, and third color light, and a second electrode above the emission unit, the metal oxide layer of the second light-emitting element being thicker than the metal oxide layer of the first light-emitting element, wherein a difference between respective distances from an upper surface of the reflection layer of the first electrode to a lower surface the second electrode in the first and second light-emitting elements is substantially equal to a difference between a thickness of the metal oxide layer of the first light-emitting element and a thickness of the metal oxide layer of the second light-emitting element.

### CROSS-REFERENCE TO RELATED APPLICATION

The present application claims priority to, and the benefit of, Korean Patent Application No. 10-2024-0128709, filed on Sep. 24, 2024, in the Korean Intellectual Property Office, the entire disclosure of which is incorporated herein by reference.

### BACKGROUND

The present disclosure herein relates to a display panel, in which a thickness of a first electrode varies depending on light-emitting elements, an electronic apparatus including the same, and a method of manufacturing a display panel.

Various types of electronic apparatuses are being developed. An electronic apparatus may include a display device, and the display device may provide information to a user.

Among electronic apparatuses, a wearable electronic apparatus, which may be worn on the body, is being developed. As one example of wearable electronic apparatuses, there is a device that may be mounted on the head of a user, and such a device may be referred to as, for example, a head-mounted device (HMD). Because a device such as an HMD is located close to a user, a solution is required to reduce a screen door effect (SDE) in which boundaries between pixels are viewed by the user.

### SUMMARY

The present disclosure provides a display panel with improved light emission efficiency. The present disclosure also provides an electronic apparatus including the display panel. The present disclosure also provides a method of manufacturing the display panel.

One or more embodiments of the present disclosure provides a display panel including a first light-emitting element including a (1-1)-th electrode including a reflection layer, and a metal oxide layer above the reflection layer, a first emission unit above the (1-1)-th electrode and configured to generate first color light, second color light, and third color light, and a (2-1)-th electrode above the first emission unit, and a second light-emitting element including a (1-2)-th electrode including a reflection layer, and a metal oxide layer above the reflection layer and that is thicker than the metal oxide layer of the (1-1)-th electrode, a second emission unit above the (1-2)-th electrode and configured to generate the first color light, the second color light, and the third color light, and a (2-2)-th electrode above the second emission unit, wherein a difference between a distance from an upper surface of the reflection layer of the (1-1)-th electrode to a lower surface of the (2-1)-th electrode and a distance from an upper surface of the reflection layer of the (1-2)-th electrode to a lower surface of the (2-2)-th electrode is substantially equal to a difference between a thickness of the metal oxide layer of the (1-1)-th electrode and a thickness of the metal oxide layer of the (1-2)-th electrode.

The first emission unit and the second emission unit may be integrated and may have a same stacked structure.

The first emission unit may include a first emission layer configured to generate the third color light, a first charge generation layer above the first emission layer, a second emission layer above the first charge generation layer, and configured to generate the first color light, a second charge generation layer above the second emission layer, and a third emission layer above the second charge generation layer, and configured to generate the second color light.

The display panel may further include a third light-emitting element including a (1-3)-th electrode including a reflection layer and a metal oxide layer above the reflection layer and that is thicker than the metal oxide layer of the (1-2)-th electrode, a third emission unit above the (1-3)-th electrode and configured to generate the first color light, the second color light, and the third color light, and a (2-3)-th electrode above the third emission unit, wherein a difference between a distance from an upper surface of the reflection layer of the (1-2)-th electrode to a lower surface of the (2-2)-th electrode and a distance from an upper surface of the reflection layer of the (1-3)-th electrode to a lower surface of the (2-3)-th electrode is substantially equal to a difference between the thickness of the metal oxide layer of the (1-2)-th electrode and a thickness of the metal oxide layer of the (1-3)-th electrode.

The (1-1)-th electrode may further include an auxiliary metal oxide layer above the metal oxide layer, and defining an opening.

The display panel may further include a base insulation layer under the (1-1)-th electrode, and contacting the (1-1)-th electrode, and a first inorganic layer above the base insulation layer, and defining a first opening overlapping the (1-1)-th electrode and exposing the (1-1)-th electrode.

The (1-2)-th electrode may be above the first inorganic layer and may contact the first inorganic layer.

The display panel may further include a second inorganic layer above the first inorganic layer, defining a first opening overlapping the (1-1)-th electrode and corresponding to the first opening of the first inorganic layer, and defining a second opening overlapping the (1-2)-th electrode and exposing the (1-2)-th electrode are defined.

The display panel may further include an organic layer above the second inorganic layer, defining a first opening corresponding to the first opening of the second inorganic layer, and defining a second opening corresponding to the second opening of the second inorganic layer.

The display panel may further include a thin-film encapsulation layer covering the first light-emitting element and the second light-emitting element, a first color filter above the thin-film encapsulation layer and overlapping the first light-emitting element, and a second color filter above the thin-film encapsulation layer and overlapping the second light-emitting element.

In one or more embodiments of the present disclosure, a method of manufacturing a display panel includes forming, above a base insulation layer, a (1-1)-th electrode including a reflection layer, and a metal oxide layer above the reflection layer, forming a first inorganic layer covering the (1-1)-th electrode, forming, above the first inorganic layer, a (1-2)-th electrode including a reflection layer, and a metal oxide layer above the reflection layer that is thicker than the metal oxide layer of the (1-1)-th electrode, forming a second inorganic layer covering the (1-2)-th electrode, forming, in the first inorganic layer and the second inorganic layer, a first opening exposing the (1-1)-th electrode, forming, in the second inorganic layer, a second opening exposing the (1-2)-th electrode, forming, above the (1-1)-th electrode and the (1-2)-th electrode, an emission unit configurated to generate first color light, second color light, and third color light, and forming a second electrode above the emission unit.

A difference between a distance from an upper surface of the reflection layer of the (1-1)-th electrode to a lower surface of the second electrode and a distance from an upper surface of the reflection layer of the (1-2)-th electrode to the lower surface of the second electrode may be substantially equal to a difference between a thickness of the metal oxide layer of the (1-1)-th electrode and a thickness of the metal oxide layer of the (1-2)-th electrode.

The (1-1)-th electrode may further include an auxiliary metal oxide layer above the metal oxide layer, wherein forming the first opening includes forming an opening corresponding to the first opening in the auxiliary metal oxide layer.

The method may further include forming an organic layer above the second inorganic layer, wherein forming the first opening including forming an opening corresponding to the first opening in the organic layer.

The method may further include forming a thin-film encapsulation layer above the second electrode, and forming, above the thin-film encapsulation layer, a first color filter overlapping the (1-1)-th electrode, and a second color filter overlapping the (1-2)-th electrode.

In one or more embodiments of the present disclosure, an electronic apparatus includes a display panel, and a processor configured to control a driving of the display panel, wherein the display panel includes a first light-emitting element including a (1-1)-th electrode including a reflection layer, and a metal oxide layer above the reflection layer, a first emission unit above the (1-1)-th electrode and configured to generate first color light, second color light, and third color light, and a (2-1)-th electrode above the first emission unit, and a second light-emitting element including a (1-2)-th electrode including a reflection layer, and a metal oxide layer above the reflection layer and that is thicker than the metal oxide layer of the (1-1)-th electrode, a second emission unit above the (1-2)-th electrode and configured to generate the first color light, the second color light, and the third color light, and a (2-2)-th electrode above the second emission unit, and wherein a difference between a distance from an upper surface of the reflection layer of the (1-1)-th electrode to a lower surface of the (2-1)-th electrode and a distance from an upper surface of the reflection layer of the (1-2)-th electrode to a lower surface of the (2-2)-th electrode is substantially equal to a difference between a thickness of the metal oxide layer of the (1-1)-th electrode and a thickness of the metal oxide layer of the (1-2)-th electrode.

The electronic apparatus may further include a frame accommodating the display panel, and a lens accommodated inside the frame and overlapping the display panel.

The electronic apparatus may include a virtual reality headset.

The first emission unit and the second emission unit may be integrated and may have a same stacked structure.

The (1-1)-th electrode may further include an auxiliary metal oxide layer above the metal oxide layer and defining an opening.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain aspects of the present disclosure. In the drawings:

FIG. 1A is a block diagram of an electronic apparatus according to one or more embodiments of the present disclosure;

FIG. 1B is an exploded perspective view of an electronic apparatus according to one or more embodiments of the present disclosure;

FIG. 2A is a perspective view of a display panel according to one or more embodiments of the present disclosure;

FIG. 2B is a plan view of a display panel according to one or more embodiments of the present disclosure;

FIG. 2C is a cross-sectional view of a display panel according to one or more embodiments of the present disclosure;

FIG. 3 is a cross-sectional view illustrating comparison of first to third light-emitting elements according to one or more embodiments of the present disclosure; and

FIGS. 4 to 11 are cross-sectional views illustrating a method of manufacturing a display panel according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

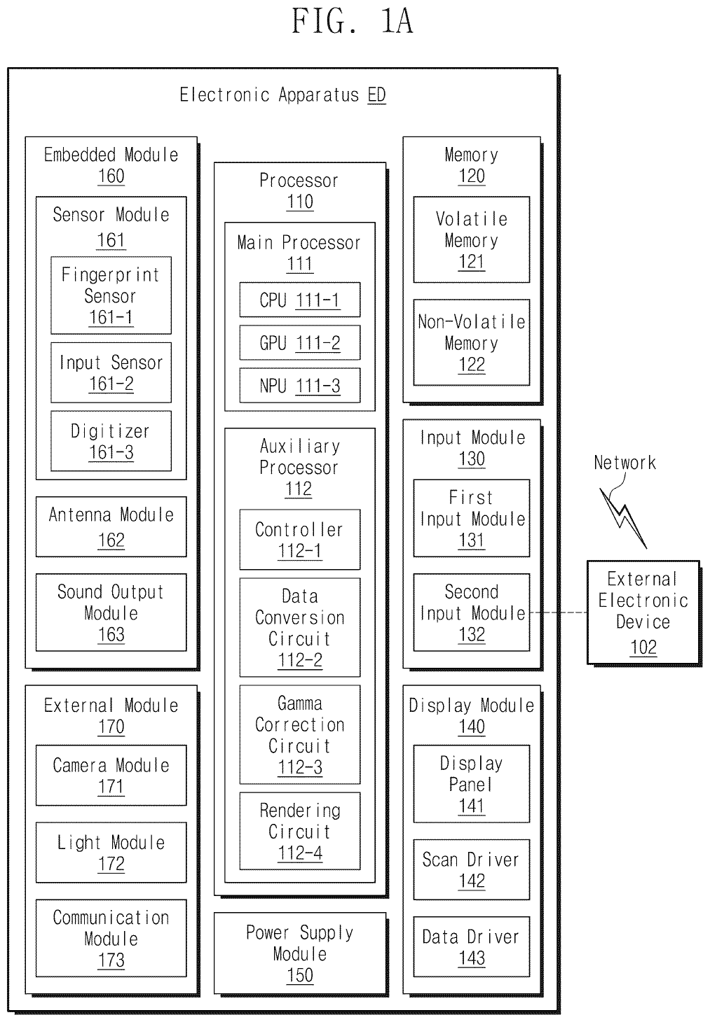

FIG. 1A is a block diagram of an electronic apparatus ED according to one or more embodiments of the present disclosure. FIG. 1B is an exploded perspective view of an electronic apparatus ED according to one or more embodiments of the present disclosure.

The electronic apparatus ED according to one or more embodiments of the present disclosure includes a display module 140. As illustrated in FIG. 1A, the electronic apparatus ED outputs various pieces of information through the display module 140 within an operation system. When a processor 110 executes an application stored in a memory 120, the display module 140 provides application information to a user through a display panel 141. That is, the processor 110 controls a driving of the display panel 141.

The processor 110 acquires an external input through an input module 130 or a sensor module 161, and executes an application corresponding to the external input. For example, when a user chooses a camera icon displayed on the display panel 141, the processor 110 acquires a user's input through an input sensor 161-2, and activates a camera module 171. The processor 110 transmits image data corresponding to an acquired captured image to the display module 140 through the camera module 171. The display module 140 may display an image corresponding to the captured image through the display panel 141.

For another example, when personal information authentication is executed in the display module 140, a fingerprint sensor 161-1 acquires, as input data, fingerprint information that has been input. The processor 110 compares the input data that is acquired through the fingerprint sensor 161-1 with authentication data stored in the memory 120, and executes an application according to the result of comparison. The display module 140 may display information, which has been executed according to the logic of the application, through the display panel 141.

For another example, when a music streaming icon is chosen in the display module 140, the processor 110 acquires a user's input through the input sensor 161-2, and activates a music streaming application stored in the memory 120. When a music execution command is input in the music streaming application, the processor 110 activates a sound output module 163 and provides, to the user, sound information corresponding to the music execution command.

In the above, an operation of the electronic apparatus ED has been briefly described. Components of the electronic apparatus ED will be described in detail below. Some of the components of the electronic apparatus ED to be described later may be integrated and provided as a single component, and one component may be divided into two or more components and provided.

Referring to FIG. 1A, the electronic apparatus ED may communicate with an external electronic apparatus 102 through a network (for example, a short-range wireless communication network or long-distance wireless communication network). According to one or more embodiments, the electronic apparatus ED may include the processor 110, the memory 120, the input module 130, the display module 140, a power supply module 150, an embedded module 160, and an external module 170.

According to one or more embodiments, at least one of the aforementioned components of the electronic apparatus ED may be omitted, or one or more other components may be added. According to one or more embodiments, some components (for example, the sensor module 161, an antenna module 162, or the sound output module 163) among the aforementioned components may be integrated into another component (for example, the display module 140).

The processor 110 may execute software to control at least one other component (for example, a hardware or software component), of the electronic apparatus ED, which is connected to the processor 110, and may perform various types of data processing or computations. According to one or more embodiments, as at least part of the data processing or the computations, the processor 110 may store data or a command received from other components (for example, the input module 130, the sensor module 161, or a communication module 173) in a volatile memory 121, may process the command or data stored in the volatile memory 121, and result data may be stored in a non-volatile memory 122.

The processor 110 may include a main processor 111 and an auxiliary processor 112. The main processor 111 may include at least one of a central processing unit (CPU) 111-1 or an application processor (AP). The main processor 111 may further include one or more among a graphic processing unit (GPU) 111-2, a communication processor (CP), and an image signal processor (ISP). The main processor 111 may further include a neural processing unit (NPU) 111-3. The neural processing unit may be a processor specialized in processing an artificial intelligence model, and the artificial intelligence model may be generated through machine learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-networks, or a combination of two or more thereof, but is not limited to the above examples. The artificial intelligence model may include a software structure, additionally or generally, in addition to a hardware structure. At least two among the aforementioned processing units and the processors may be implemented as one integrated component (for example, a single chip) or may each be implemented as an independent component (for example, a plurality of chips).

The auxiliary processor 112 may include a controller 112-1. The controller 112-1 may include an interface conversion circuit and a timing control circuit. The controller 112-1 may receive an image signal from the main processor 111, may convert a data format of the image signal to comply with an interface specification for the display module 140, and then output image data. The controller 112-1 may output various control signals that are necessary to drive the display module 140.

The auxiliary processor 112 may further include a data conversion circuit 112-2, a gamma correction circuit 112-3, a rendering circuit 112-4, and the like. The data conversion circuit 112-2 may receive the image data from the controller 112-1, and may compensate for the image data to display an image having a desired luminance according to the properties of the electronic apparatus ED, a user's setting, or the like, or may convert the image data for reduction in power consumption, compensation for afterimage, or the like. The gamma correction circuit 112-3 may convert the image data, a gamma reference voltage, or the like such that the image displayed in the electronic apparatus ED has a desired gamma property. The rendering circuit 112-4 may receive the image data from the controller 112-1, and may render the image data in consideration of a pixel arrangement, etc. of the display panel 141 applied to the electronic apparatus ED. At least one of the data conversion circuit 112-2, the gamma correction circuit 112-3, or the rendering circuit 112-4 may be integrated into another component (for example, the main processor 111 or the controller 112-1). At least one of the data conversion circuit 112-2, the gamma correction circuit 112-3, or the rendering circuit 112-4 may also be integrated into a data driver 143 to be described later.

The memory 120 may store various data used by at least one component (for example, the processor 110 or the sensor module 161) of the electronic apparatus ED, and may store input data or output data about commands related thereto. The memory 120 may include at least one of the volatile memory 121 or the non-volatile memory 122.

The input module 130 may receive commands or data, which will be used in a component (for example, the processor 110, the sensor module 161, or the sound output module 163) of the electronic apparatus ED, from the outside (for example, a user or the external electronic apparatus 102) of the electronic apparatus ED.

The input module 130 may include a first input module 131 to which commands or data are input from a user and a second input module 132 to which commands or data are input from the external electronic apparatus 102. The first input module 131 may include a microphone, a mouse, a keyboard, a key (for example, a button) or a pen (for example, a passive pen or an active pen). The second input module 132 may support a designated protocol that allows wired or wireless connection with the external electronic apparatus 102. According to one or more embodiments, the second input module 132 may include a high definition multimedia interface (HDMI), a universal serial bus (USB) interface, an SD card interface, or an audio interface. The second input module 132 may include a connector, for example, a HDMI connector, a USB connector, an SD card connector, or an audio connector (for example, a headphone connector), which is capable of physical connection with the external electronic apparatus 102.

The display module 140 visually provides information to a user. The display module 140 may include a display panel 141, a scan driver 142, and a data driver 143. The display module 140 may further include a window, a chassis, and a bracket for protecting the display panel 141.

The display panel 141 may include a liquid crystal display panel, an organic light-emitting display panel, or an inorganic light-emitting display panel, and a type of the display panel 141 is not particularly limited. The display panel 141 may be a rigid display panel, or a flexible display panel that is rollable or foldable. The display module 140 may further include a supporter for supporting the display panel 141, a bracket, a heat dissipation member, or the like.

The scan driver 142 may be mounted as a driving chip on the display panel 141. In addition, the scan driver 142 may be integrated into the display panel 141. For example, the scan driver 142 may include an amorphous silicon TFT gate (ASG) driver circuit, a low temperature polycrystalline silicon (LTPS) TFT gate driver circuit, or an oxide semiconductor TFT gate (OSG) driver circuit, which is integrated in the display panel 141. The scan driver 142 receives a control signal from the controller 112-1, and outputs scans signal to the display panel 141 in response to the control signal.

The display panel 141 may further include an emission driver. The emission driver outputs an emission control signal to the display panel 141 in response to the control signal received from the controller 112-1. The emission driver may be formed separately from the scan driver 142, or may be integrated into the scan driver 142.

The data driver 143 receives the control signal from the controller 112-1, converts the image data into an analog voltage (for example, a data voltage) in response to the control signal, and then outputs data voltages to the display panel 141.

The data driver 143 may be integrated into another component (for example, the controller 112-1). The functions of the interface conversion circuit and the timing control circuit of the aforementioned controller 112-1 may also be integrated into the data driver 143.

The display module 140 may further include an emission driver, a voltage generation circuit, and the like. The voltage generation circuit may output various voltages that are necessary to drive the display panel 141.

The power supply module 150 supplies power to the components of the electronic apparatus ED. The power supply module 150 may include a battery for charging a power voltage. The battery may include a non-rechargeable primary cell, a rechargeable secondary cell, or a fuel cell. The power supply module 150 may include a power management integrated circuit (PMIC). The PMIC supplies optimized power to each of the aforementioned modules and modules to be described later. The power supply module 150 may include a wireless power transmission and reception member that is electrically connected to the battery. The wireless power transmission and reception member may include a plurality of antenna radiators in a coil shape.

The electronic apparatus ED may further include the embedded module 160 and the external module 170. The embedded module 160 may include the sensor module 161, the antenna module 162, and the sound output module 163. The external module 170 may include the camera module 171, a light module 172, and the communication module 173.

The sensor module 161 may sense an input applied by a part of the user body or an input applied by a pen of the first input module 131, and may generate an electrical signal or a data value corresponding to the input. The sensor module 161 may include at least any one among the fingerprint sensor 161-1, the input sensor 161-2, and a digitizer 161-3.

The fingerprint sensor 161-1 may generate a data value corresponding to a user's fingerprint. The fingerprint sensor 161-1 may include any one of an optical fingerprint sensor or a capacitive fingerprint sensor.

The input sensor 161-2 may generate a data value corresponding to coordinate information about the input applied by the pen or the input applied by a part of the user body. The input sensor 161-2 may generate, as the data value, an amount of change in capacitance due to the input. The input sensor 161-2 may sense an input applied by the passive pen, or may transmit/receive data to/from the active pen.

The input sensor 161-2 may also measure bio-signals such as blood pressure, hydration, or body fat. For example, when a user does not move during a certain period of time while touching a sensor layer or a sensing panel with a part of the user body, the input sensor 161-2 may sense the bio-signals on the basis of changes in electric field caused by the part of the user body, and output, to the display module 140, information desired by the user.

The digitizer 161-3 may generate a data value corresponding to coordinate information about the input applied by the pen. The digitizer 161-3 may generate, as the data value, an amount of electromagnetic changes due to the input. The digitizer 161-3 may sense an input applied by the passive pen, or may transmit/receive data to/from the active pen.

At least one among the fingerprint sensor 161-1, the input sensor 161-2, and the digitizer 161-3 may also be implemented as a sensor layer formed on the display panel 141 through a continuous process. The fingerprint sensor 161-1, the input sensor 161-2, and the digitizer 161-3 may be located on/over the display panel 141, and any one among the fingerprint sensor 161-1, the input sensor 161-2, and the digitizer 161-3, for example, the digitizer 161-3 may be located under the display panel 141.

At least two among the fingerprint sensor 161-1, the input sensor 161-2, and the digitizer 161-3 may be formed to be integrated into a single sensing panel through the same process. When integrated into the single sensing panel, the sensing panel may be located between the display panel 141 and a window located on/over the display panel 141. According to one or more embodiments, the sensing panel may also be located on the window, and the location of the sensing panel is not particularly limited.

At least one among the fingerprint sensor 161-1, the input sensor 161-2, and the digitizer 161-3 may be embedded in the display panel 141. That is, at least one among the fingerprint sensor 161-1, the input sensor 161-2, and the digitizer 161-3 may be simultaneously formed through a process for forming elements (for example, a light-emitting element, a transistor, or the like) included in the display panel 141.

In addition, the sensor module 161 may generate an electrical signal or a data value corresponding to an internal state or an external state of the electronic apparatus ED. For example, the sensor module 161 may further include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illumination sensor.

The antenna module 162 may include one or more antennae for transmitting a signal or power to the outside or receiving a signal or power from the outside.

According to one or more embodiments, the communication module 173 may transmit a signal to the external electronic apparatus, or receive a signal from the external electronic apparatus through an antenna suitable for a communication method. An antenna pattern of the antenna module 162 may be integrated into one component (for example, the display panel 141) of the display module 140, the input sensor 161-2, or the like.

The sound output module 163 may be a unit for outputting a sound signal to the outside of the electronic apparatus ED, and for example, may include a speaker that is used for general purposes such as multimedia playback or recording playback, and a receiver that is used exclusively for receiving phone calls. According to one or more embodiments, the receiver may be formed integrally with or separately from the speaker. A sound output pattern of the sound output module 163 may be integrated into the display module 140.

The camera module 171 may capture still images and moving images. According to one or more embodiments, the camera module 171 may include one or more lenses, an image sensor, or an image signal processor. The camera module 171 may further include an infrared camera that can measure presence/absence of a user, a user's location, user's gaze, and the like.

The light module 172 may provide light. The light module 172 may include a light-emitting diode or a xenon lamp. The light module 172 may operate in conjunction with or operate independently from the camera module 171.

The communication module 173 may assist in establishment of a wired or wireless communication channel between the electronic apparatus ED and the external electronic apparatus 102, and assist in communication through the established communication channel. The communication module 173 may include any one among a wireless communication module such as a cellular communication module, a short-range wireless communication module, or a global navigation satellite system (GNSS) communication module and a wired communication module such as a local area network (LAN) communication module or a power line communication module, or may include both thereof. The communication module 173 may communicate with the external electronic apparatus 102 through a short-range communication network such as Bluetooth® (Bluetooth® being a registered trademark of Bluetooth Sig, Inc., Kirkland, WA), Wi-Fi® direct (Wi-Fi® being a registered trademark of the non-profit Wi-Fi Alliance), or infrared data association (IrDA), or through a long-distance communication network such as a cellular network, Internet, or a computer network (for example, LAN or WAN). Various types of the communication modules 173 described above may be implemented as a single chip or may each be implemented as an individual chip.

The input module 130, the sensor module 161, the camera module 171, and the like may be used for controlling the operation of the display module 140 in conjunction with the processor 110.

The processor 110 outputs commands or data to the display module 140, the sound output module 163, the camera module 171, or the light module 172, on the basis of the input data received from the input module 130. For example, the processor 110 may generate image data corresponding to the input data applied through the mouse, the active pen, or the like and output the image data to the display module 140, or may generate command data corresponding to the input data and output the command data to the camera module 171 or the light module 172. When the input data are not received for a certain period of time from the input module 130, the processor 110 may switch an operation mode of the electronic apparatus ED to a low power mode or a sleep mode, thereby reducing power consumed in the electronic apparatus ED.

The processor 110 outputs commands or data to the display module 140, the sound output module 163, the camera module 171, or the light module 172, on the basis of sensed data received from the sensor module 161. For example, the processor 110 compares authentication data applied by the fingerprint sensor 161-1 with the authentication data stored in the memory 120, and then the processor 110 may execute an application according to the result of comparison. The processor 110 may execute a command or output corresponding image data to the display module 140, on the basis of the sensed data detected by the input sensor 161-2 or the digitizer 161-3. When the temperature sensor is included in the sensor module 161, the processor 110 may receive temperature data about the temperature measured by the sensor module 161, and may further perform luminance correction, etc., on the image data, on the basis of the temperature data.

The processor 110 may receive measured data about presence/absence of a user, a user's location, user's gaze, or the like from the camera module 171. The processor 110 may further perform luminance correction, etc., on the image data on the basis of the measured data. For example, the processor 110, which has determined the presence or absence of a user through the input from the camera module 171, may output image data with corrected luminance to the display module 140 through the data conversion circuit 112-2 or the gamma correction circuit 112-3.

Some components of the above components may be connected to each other through a communication method between peripheral devices, for example, a bus, general purpose input/output (GPIO), a serial peripheral interface (SPI), a mobile industry processor interface (MIPI), or an ultra path interconnect (UPI) link, and may mutually exchange signals (for example, commands or data). The processor 110 may communicate with the display module 140 through a mutually agreed-upon interface, and for example, any one of the aforementioned communication methods may be used. One or more embodiments of the present disclosure is not limited to the aforementioned communication methods.

The electronic apparatus ED according to one or more embodiments of the present disclosure may be various types or forms of apparatuses. For example, the electronic apparatus ED may include at least one of a portable communication device (for example, a smart phone), a tablet device, a portable multimedia device, a wearable device, or a home appliance device. The electronic apparatus ED according to one or more embodiments of the present disclosure is not limited to the aforementioned devices. Some of the components of the electronic apparatus ED described with reference to FIG. 1A may be omitted depending on the type or form of the electronic apparatus ED. Hereinafter, the display panel 141 in FIG. 1A will be described below as a display panel DP.

FIG. 1B illustrates a virtual reality headset (or a head-mounted device) as one example of a wearable device. The virtual reality headset may include a see-through-type headset for providing augmented reality (AR) based on actual external objects, or a see-closed-type headset for providing virtual reality (VR) to a user with a screen that is independent from external objects.

Referring to FIG. 1B, an electronic apparatus ED may include a display panel DP and a lens(es) LS opposed to the display panel DP. In addition, the electronic apparatus ED may include a frame FR for accommodating the display panel DP and the lens LS. The frame FR may include a main frame MF and a cover frame CFR. A fixing part FP may be coupled to the main frame MF and worn on a user's head.

The cover frame CFR may be coupled to the main frame MF, and the lens LS and the display panel DP may be located in a space therebetween. The main frame MF may provide a space in which the lens LS and the display panel DP are accommodated.

In a state in which a user is wearing the headset, the lens LS may be located between the display panel DP and the user. The lens LS may provide an image to the user by making the image generated from the display panel DP pass therethrough. For example, the lens LS may include various types of lenses such as a multi-channel lens, a convex lens, a concave lens, a spherical lens, an aspherical lens, a single lens, a compound lens, a standard lens, a narrow angle lens, a wide angle lens, a fixed focus lens, and a varifocal lens. The lens LS may include a first lens LS1 and a second lens LS2. The first lens LS1 and the second lens LS2 may be located to respectively correspond to locations of the left eye and the right eye of the user.

The display panel DP may be coupled to the main frame MF in a fixed state, or may be coupled thereto in a detachable state. The display panel DP will be described in more detail later.

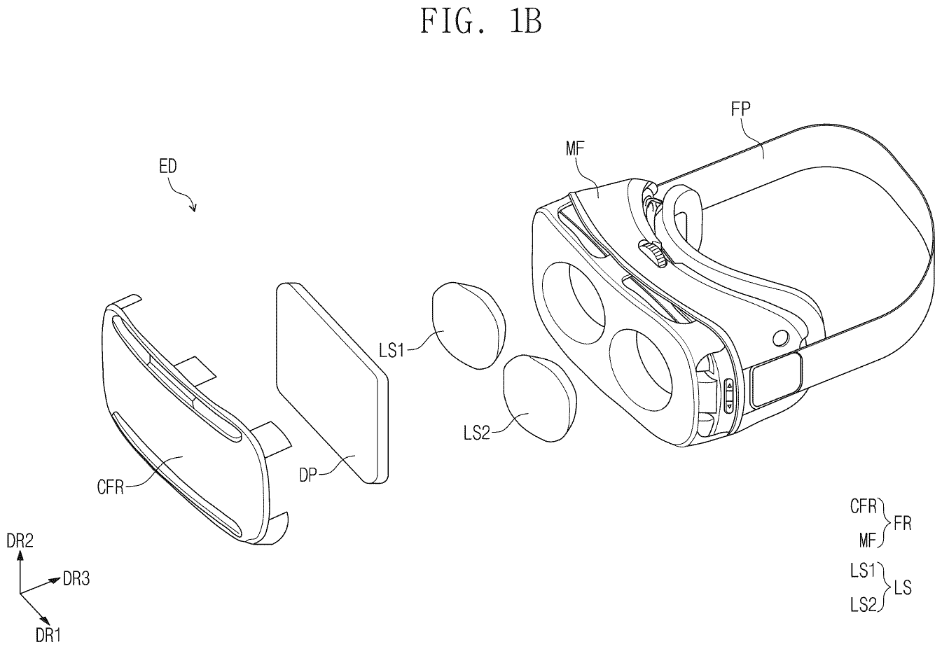

FIG. 2A is a perspective view of a display panel DP according to one or more embodiments of the present disclosure. FIG. 2B is a plan view of a display panel DP according to one or more embodiments of the present disclosure. FIG. 2C is a cross-sectional view of a display panel DP according to one or more embodiments of the present disclosure.

Referring to FIG. 2A, the display panel DP may include a display region AA and a non-display region NAA. The non-display region NAA may surround the display region AA (e.g., in plan view). Pixels may be located in the display region AA.

FIG. 2B illustrates an enlarged view of the display region AA. The display region AA may include a first light-emitting region PXA-1, a second light-emitting region PXA-2, and a third light-emitting region PXA-3. The display region AA may further include a non-light emitting region NPXA that is located around the first light-emitting region PXA-1, the second light-emitting region PXA-2, and the third light-emitting region PXA-3. A corresponding pixel is located in each of the first light-emitting region PXA-1, the second light-emitting region PXA-2, and the third light-emitting region PXA-3.

The first light-emitting region PXA-1, the second light-emitting region PXA-2, and the third light-emitting region PXA-3 may each provide light of different wavelength bands (or light of different peak wavelengths) to the outside. The first light-emitting region PXA-1 may emit first color light. The second light-emitting region PXA-2 may emit second color light that is different from the first color light. The third light-emitting region PXA-3 may emit third color light that is different in wavelength band from the first color light and the second color light. The first light-emitting region PXA-1 may provide blue color light, the second light-emitting region PXA-2 may provide green color light, and the third light-emitting region PXA-3 may provide red color light.

Among the first to third light-emitting regions PXA-1, PXA-2, and PXA-3, the first light-emitting region PXA-1 may have the greatest area, and the second light-emitting region PXA-2 may have the smallest area. However, this is an example, and an area comparison between the first to third light-emitting regions PXA-1, PXA-2, and PXA-3 is not limited thereto. In one embodiment of the present invention, the third light-emitting area PXA-1 may have the greatest area, and the second light-emitting area PXA-2 may have the smallest area. In FIG. 2B, the first light-emitting region PXA-1 and the third light-emitting region PXA-3 may be alternately arranged along a first direction DR1 in one pixel row, and the second light-emitting region PXA-2 may be arranged in another pixel row different from the pixel row where the first light-emitting region PXA-1 and the third light-emitting region PXA-3 are arranged. However, such an arrangement of the first to third light-emitting regions PXA-1, PXA-2, and PXA-3 is an example, and the arrangement of the first to third light-emitting regions PXA-1, PXA-2, and PXA-3 is not limited thereto.

Referring to FIG. 2C, the display panel DP may include a base layer BS, a driving element layer DP-CL located on the base layer BS, a display element layer DP-ED located on the driving element layer DP-CL, and an encapsulation layer TFE located on the display element layer DP-ED. In addition, the display panel DP may further include a color filter layer CFL located on the encapsulation layer TFE.

The base layer BS may include a glass substrate or a synthetic resin substrate. Referring to FIG. 2C, the driving element layer DP-CL is located on the base layer BS. The driving element layer DP-CL includes pixel circuits respectively located in the first to third light-emitting regions PXA-1, PXA-2, and PXA-3. FIG. 2C illustrates one transistor 100PC included in the pixel circuit.

A first insulation layer 10 is located on an upper surface of the base layer BS. The first insulation layer 10 may correspond to a buffer layer, and may improve adhesion between the base layer BS and semiconductor patterns SC, AL, DR, and SCL. The first insulation layer 10 may also be formed of multiple layers. The first insulation layer 10 may include at least one of silicon oxide, silicon nitride, or silicon oxynitride. For example, the first insulation layer 10 may include a structure in which a silicon oxide layer and a silicon nitride layer are alternately stacked.

The semiconductor patterns SC, AL, DR, and SCL may be located on the first insulation layer 10. The semiconductor patterns SC, AL, DR, and SCL may include polysilicon. However, one or more embodiments of the present disclosure is not limited thereto, and the semiconductor patterns SC, AL, DR, and SCL may also include amorphous silicon, low-temperature polycrystalline silicon, or an oxide semiconductor.

FIG. 2C only illustrates some of the semiconductor patterns SC, AL, DR, and SCL, and the semiconductor patterns SC, AL, DR, and SCL may further be located in another region on a plane. The semiconductor patterns SC, AL, DR, and SCL may be arranged in accordance with a corresponding rule across the first to third light-emitting regions PXA-1, PXA-2, and PXA-3 in FIG. 2B.

The semiconductor patterns SC, AL, DR, and SCL may have different electrical properties depending on whether to be doped or not. The semiconductor patterns SC, AL, DR, and SCL may include first regions SC, DR, and SCL with high conductivity and a second region AL with low conductivity. The first regions SC, DR, and SCL may be doped with an N-type dopant or a P-type dopant. A P-type transistor may include a doped region that is doped with the P-type dopant, and an N-type transistor may include a doped region that is doped with the N-type dopant. The second region AL may be an undoped region, or lightly doped region compared to the first regions SC, DR, and SCL.

The first regions SC, DR, and SCL may have a greater conductivity than the second region AL, and thus may substantially serve as electrodes or signal lines. The second region AL may substantially correspond to an active region AL (or a channel) of the transistor 100PC. In other words, the second region AL of the semiconductor patterns SC, AL, DR, and SCL may be the active region AL of the transistor 100PC, other parts SC and DR may be a source region SC or drain region DR of the transistor 100PC, and another part SCL may be a connection electrode or a connection signal line SCL.

FIG. 2C illustrates a portion of the connection signal line SCL formed from the semiconductor patterns SC, AL, DR, and SCL. In one or more embodiments, the connection signal line SCL may be electrically connected to the drain region DR of the transistor 100PC on a plane.

A second insulation layer 20 may be located on the first insulation layer 10. The second insulation layer 20 may overlap the first to third light-emitting regions PXA-1, PXA-2, and PXA-3 and the non-light emitting region NPXA in common, and may cover the semiconductor patterns SC, AL, DR, and SCL. The second insulation layer 20 may be an inorganic layer and/or an organic layer, and may have a single- or multi-layered structure. The second insulation layer 20 may include at least one among aluminum oxide, titanium oxide, silicon oxide, silicon nitride, silicon oxynitride, zirconium oxide, and hafnium oxide.

The second insulation layer 20 may be a single-layered silicon oxide layer. Unless otherwise explained below, an insulation layer of the driving element layer DP-CL to be described later may be an inorganic layer or an organic layer, and may have a single- or multi-layered structure. The inorganic layer may include at least one of the aforementioned materials, but is not limited thereto.

A gate GT of the transistor 100PC is located on the second insulation layer 20. The gate GT may be a portion of a metal pattern. The gate GT overlaps the active region AL. The gate GT may serve as a mask during a process of doping or reducing the semiconductor patterns SC, AL, DR, and SCL.

A third insulation layer 30 may be located on the second insulation layer 20, and may cover the gate GT. The third insulation layer 30 may overlap the first to third light-emitting regions PXA-1, PXA-2, and PXA-3 and the non-light emitting region NPXA in common.

A fourth insulation layer 40 may be located on the third insulation layer 30. A connection electrode CNE may be located on the fourth insulation layer 40. The connection electrode CNE may be connected to the connection signal line SCL through a contact hole CNT1 that penetrates the first, second, third, and fourth insulation layers 10, 20, 30, and 40.

A fifth insulation layer 50 and a sixth insulation layer 60 may be sequentially located on the fourth insulation layer 40. The sixth insulation layer 60 may be an organic layer. The sixth insulation layer 60 may provide an upper surface that is flatter than those of the insulation layers 10, 20, 30, 40, and 50 located thereunder.

The display element layer DP-ED may be located on the driving element layer DP-CL. The display element layer DP-ED may be directly located on the sixth insulation layer 60, and like the sixth insulation layer 60, an uppermost insulation layer of the driving element layer DP-CL may also be defined as a base insulation layer. The display element layer DP-ED may include a light-emitting element LD.

For example, the light-emitting element LD may include an organic light-emitting material, an inorganic light-emitting material, an organic-inorganic light-emitting material, quantum dots, quantum rods, a micro LED, or a nano LED. Hereinafter, the light-emitting element LD will be described as an example of an organic light-emitting element, but is not particularly limited thereto.

FIG. 2C illustrates first to third light-emitting elements LD1, LD2, and LD3 that are respectively located in the first to third light-emitting regions PXA-1, PXA-2, and PXA-3. The first to third light-emitting elements LD1, LD2, and LD3 may each include a first electrode AE, an emission unit EU located on the first electrode AE, and a second electrode CE. The first electrode AE may be an anode, and the second electrode CE may be a cathode.

The first electrode AE may be connected to the connection electrode CNE through a contact hole CNT2 that penetrates at least the fifth insulation layer 50 and the sixth insulation layer 60. The number of the insulation layers through which the contact hole CNT2 passes may vary depending on the first to third light-emitting elements LD1, LD2, and LD3.

The emission units EU of the first to third light-emitting elements LD1, LD2, and LD3 may have an integrated shape, and the second electrodes CE of the first to third light-emitting elements LD1, LD2, and LD3 may have an integrated shape. The emission unit EU and the second electrode CE overlap the first to third light-emitting regions PXA-1, PXA-2, and PXA-3 and the non-light emitting region NPXA in common.

The first to third light-emitting elements LD1, LD2, and LD3 include the respective first electrodes AE that are distinguished from one another, and to explain a difference between the first electrodes AE, the first electrode AE of the first light-emitting element LD1 is described as a (1-1)-th electrode AE1, the first electrode AE of the second light-emitting element LD2 is described as a (1-2)-th electrode AE2, and the first electrode AE of the third light-emitting element LD3 is described as a (1-3)-th electrode AE3.

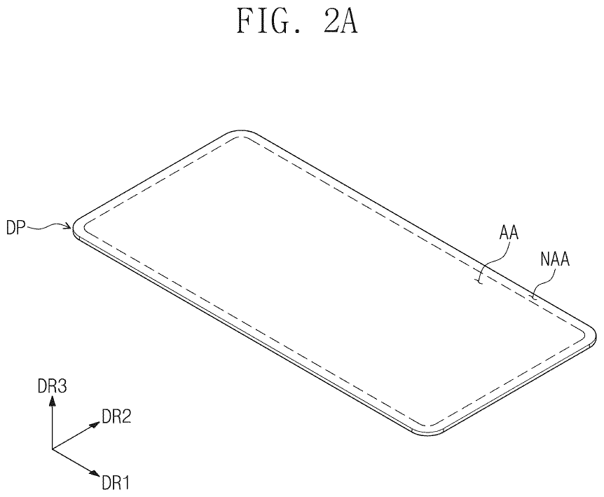

The (1-1)-th electrode AE1, the (1-2)-th electrode AE2, and the (1-3)-th electrode AE3 may each have a multi-layered structure. As can also be seen in FIG. 3, the (1-1)-th electrode AE1, the (1-2)-th electrode AE2, and the (1-3)-th electrode AE3 may each include a reflection layer RL, and a metal oxide layer OL located on the reflection layer RL. The reflection layer RL may include any one of silver (Ag), magnesium (Mg), copper (Cu), aluminum (AI), platinum (Pt), or gold (Au), which has high reflectance. For example, a reflection electrode RE may include silver (Ag).

The metal oxide layer OL may include indium tin oxide (ITO), indium zinc oxide (IZO), indium gallium zinc oxide (IGZO), zinc oxide (ZnOx), indium oxide (In₂O₃), or aluminum doped zinc oxide (AZO), which facilitates hole injection. In one or more embodiments, the metal oxide layer OL (e.g., another metal oxide layer) may further be located under the reflection layer RL so as to increase adhesion between the first electrode AE and the insulation layer located thereunder.

Each of the (1-1)-th electrode AE1, the (1-2)-th electrode AE2, and the (1-3)-th electrode AE3 may further include an auxiliary metal oxide layer SOL in which an opening A-OP is defined. The auxiliary metal oxide layer SOL protects the metal oxide layer OL in a dry etching process performed during a manufacturing process. Meanwhile, in the dry etching process, the auxiliary metal oxide layer SOL is removed, and thus the opening A-OP is formed.

The auxiliary metal oxide layer SOL may include a metal oxide. The auxiliary metal oxide layer SOL may include a different metal oxide from the metal oxide layer OL. The metal oxide layer OL may include indium gallium oxide (IGO) or indium gallium zinc oxide (IGZO). The auxiliary metal oxide layer SOL may be omitted in one or more embodiments of the present disclosure.

The (1-1)-th electrode AE1 may be in contact with an upper surface of the sixth insulation layer 60. At least one inorganic layer 70 is located on the sixth insulation layer 60. A first inorganic layer 71 covering the (1-1)-th electrode AE1 is located on the sixth insulation layer 60. The first inorganic layer 71 overlaps the first to third light-emitting regions PXA-1, PXA-2, and PXA-3 and the non-light emitting region NPXA in common. The first inorganic layer 71 protects the (1-1)-th electrode AE1 in a wet etching process performed during the manufacturing process. An opening 71-OP partially exposing the (1-1)-th electrode AE1 is defined in the first inorganic layer 71.

The (1-2)-th electrode AE2 may be in contact with an upper surface of the first inorganic layer 71. A second inorganic layer 72 covering the (1-2)-th electrode AE2 is located on the first inorganic layer 71. The second inorganic layer 72 protects the (1-2)-th electrode AE2 in a wet etching process performed during the manufacturing process. An opening 72-OP partially exposing the (1-1)-th electrode AE1 and an opening 72-OP partially exposing the (1-2)-th electrode AE2 are defined in the second inorganic layer 72.

The (1-3)-th electrode AE3 may be in contact with an upper surface of the second inorganic layer 72. A pixel-defining film 80 overlapping the (1-3)-th electrode AE3 is located on the second inorganic layer 72. The pixel-defining film 80 may be an organic layer.

An opening 80-OP partially exposing the (1-1)-th electrode AE1, an opening 80-OP partially exposing the (1-2)-th electrode AE2, and an opening 80-OP partially exposing the (1-3)-th electrode AE3 are defined in the pixel-defining film 80. At least some of the openings 71-OP, 72-OP, and 80-OP that are respectively formed in the first inorganic layer 71, the second inorganic layer 72, and the pixel-defining film 80 may be formed through a single process. The openings 71-OP, 72-OP, and 80-OP may be formed through the same process, or may be formed through different processes depending on the first to third light-emitting regions PXA-1, PXA-2, and PXA-3.

The emission unit EU is located on the first electrode AE and the pixel-defining film 80 so as to overlap the first to third light-emitting regions PXA-1, PXA-2, and PXA-3 and the non-light emitting region NPXA in common. The second electrode CE is located on the emission unit EU.

Each of the emission unit EU and the second electrode CE, which may have an integrated shape, may also be divided into different respective parts in a region. A portion of the emission unit EU overlapping the (1-1)-th electrode AE1 may be defined as a first emission unit, and a portion of the second electrode CE overlapping the (1-1)-th electrode AE1 may be defined as a (2-1)-th electrode. Likewise, a portion of the emission unit EU overlapping the (1-2)-th electrode AE2 may be defined as a second emission unit, and a portion of the second electrode CE overlapping the (1-2)-th electrode AE2 may be defined as a (2-2)-th electrode. A portion of the emission unit EU overlapping the (1-3)-th electrode AE3 may be defined as a third emission unit, and a portion of the second electrode CE overlapping the (1-3)-th electrode AE3 may be defined as a (2-3)-th electrode. In addition, a portion of each of the emission unit EU and the second electrode CE overlapping the non-light emitting region NPXA may also be described separately from a portion overlapping the aforementioned first to third light-emitting regions PXA-1, PXA-2, and PXA-3.

A thin-film encapsulation layer TFE may be located on the emission unit EU. The thin-film encapsulation layer TFE may protect the display element layer DP-ED from moisture, oxygen, and foreign matters such as dust particles. The encapsulation layer TFE may include at least one inorganic film (hereinafter, an inorganic encapsulation film). In addition, the encapsulation layer TFE may further include at least one organic film (hereinafter, an organic encapsulation film). The thin-film encapsulation layer TFE may include an inorganic encapsulation layer, an organic encapsulation layer, and an inorganic encapsulation layer that are sequentially stacked, but the layers that constitute the thin-film encapsulation layer TFE are not limited thereto.

The color filter layer CFL may be located on the thin-film encapsulation layer TFE. The color filter layer CFL may include a first color filter CF1 corresponding to the first light-emitting region PXA-1, a second color filter CF2 corresponding to the second light-emitting region PXA-2, and a third color filter CF3 corresponding to the third light-emitting region PXA-3. In one or more embodiments, the color filter layer CFL may further include a light-shielding pattern. The first color filter CF1 transmits first color light among the first color light, second color light, and third color light generated from the emission unit EU. The second color filter CF2 transmits the second color light among the first color light, the second color light, and the third color light generated from the emission unit EU, and the third color filter CF3 transmits the third color light among the first color light, the second color light, and the third color light generated from the emission unit EU.

The first to third color filters CF1, CF2, and CF3 may each include a polymer photosensitive resin and a colorant. In this specification, the colorant includes a pigment and a dye. A red colorant includes a red pigment and a red dye, a green colorant includes a green pigment and a green dye, and a blue colorant includes a blue pigment and a blue dye.

The color filter layer CFL may include a planarization layer PZL located on the first to third color filters CF1, CF2, and CF3. The planarization layer PZL may include an organic material.

FIG. 3 is a cross-sectional view illustrating comparison of first to third light-emitting elements LD1, LD2, and LD3 according to one or more embodiments of the present disclosure.

FIG. 3 only illustrates partial regions of the first to third light-emitting elements LD1, LD2, and LD3, that is, the regions inside the first to third light-emitting regions PXA-1, PXA-2, and PXA-3 in FIG. 2C. Accordingly, the auxiliary metal oxide layer SOL in FIG. 2C is not illustrated in FIG. 3.

FIG. 3 illustrates the first to third light-emitting elements LD1, LD2, and LD3 each including an emission unit EU that has the same stacked structure. The emission unit EU may include a hole injection layer PHIL located on a first electrode AE, a first light-emitting layer REML, a first charge generation layer CGL1, a second light-emitting layer BEML, a second charge generation layer CGL2, a third light-emitting layer GEML, and an electron transport layer METL. The hole injection layer PHIL and the electron transport layer METL may be omitted in one or more embodiments of the present disclosure.

The hole injection layer PHIL may include a hole injection/transport material doped with a P-type dopant. The electron transport layer METL may include an electron injection/transport material that contains metal. The first charge generation layer CGL1 and the second charge generation layer CGL2 may each include a first-type charge generation layer n-CGL and a second-type charge generation layer p-CGL that are stacked. The first-type charge generation layer n-CGL may be an n-type charge generation layer, and the second-type charge generation layer p-CGL may be a p-type charge generation layer.

The first light-emitting layer REML may generate third color light, the second light-emitting layer BEML may generate first color light, and the third light-emitting layer GEML may generate second color light. The first color light may be shorter in wavelength than the second color light and the third color light. The third color light may be longer in wavelength than the first color light and the second color light. The first color light may be blue color light, the second color light may be green color light, and the third color light may be red color light. However, the stacking order among the first light-emitting layer REML, the second light-emitting layer BEML and the third light-emitting layer GEML is not particularly limited.

A (1-1)-th electrode AE1, a (1-2)-th electrode AE2, and a (1-3)-th electrode AE3 have different thicknesses. Reflection layers RL of the (1-1)-th electrode AE1, the (1-2)-th electrode AE2, and the (1-3)-th electrode AE3 may have the same thickness, and metal oxide layers OL of the (1-1)-th electrode AE1, the (1-2)-th electrode AE2, and the (1-3)-th electrode AE3 may have different thicknesses.

FIG. 3 illustrates first to third resonance distances RD1, RD2, and RD3 of the first to third light-emitting elements LD1, LD2, and LD3. The first to third resonance distances RD1, RD2, and RD3 may each be defined as a distance between an upper surface of the corresponding reflection layer RL and a lower surface of a second electrode CE.

The first to third resonance distances RD1, RD2, and RD3 may be respectively determined by thicknesses T1, T2, and T3 of the metal oxide layers OL. The first resonance distance RD1 of the first light-emitting element LD1 that generates the longest wavelength light may be the greatest. Accordingly, the thickness T1 of the metal oxide layer OL of the first light-emitting element LD1 is greater than the thicknesses T2 and T3 of the metal oxide layers OL of the other light-emitting elements LD2 and LD3. The thickness T3 of the metal oxide layer OL of the third light-emitting element LD3 may be less than the thickness T2 of the metal oxide layer OL of the second light-emitting element LD2.

The first to third light-emitting elements LD1, LD2, and LD3 include the emission unit EU and the second electrode CE that are generated through the same process, and thus are substantially different from each other in only the thicknesses T1, T2, and T3 of the metal oxide layers OL. Accordingly, a difference between the first resonance distance RD1 and the second resonance distance RD2 may be substantially the same as a difference between the thickness T1 of the metal oxide layer OL of the first light-emitting element LD1 and the thickness T2 of the metal oxide layer OL of the second light-emitting element LD2. For the same reason, a difference between the second resonance distance RD2 and the third resonance distance RD3 may be substantially the same as, or may be substantially proportional to or equal to, a difference between the thickness T2 of the metal oxide layer OL of the second light-emitting element LD2 and the thickness T3 of the metal oxide layer OL of the third light-emitting element LD3.

Among the first to third light-emitting elements LD1, LD2, and LD3, the first light-emitting element LD1 having the first resonance distance RD1, which is the longest, may increase emission efficiency of the first color light that has the longest wavelength. Among the first to third light-emitting elements LD1, LD2, and LD3, the third light-emitting element LD3 having the third resonance distance RD3, which is the shortest, may increase emission efficiency of the third color light that has the shortest wavelength. Consequently, the emission efficiency of each of the first to third light-emitting elements LD1, LD2, and LD3 may be increased.

The single-layered metal oxide layer OL is illustrated with reference to FIG. 3, but the metal oxide layer OL may have a multi-layered structure. The number of stacked layers of the (1-1)-th electrode AE1 may be the greatest, and the number of stacked layers of the (1-3)-th electrode AE3 may be the smallest. The stacked structures of the first electrode AE may include a material selected from indium tin oxide (ITO), indium zinc oxide (IZO), indium gallium zinc oxide (IGZO), zinc oxide (ZnOx), indium oxide (In₂O₃), or aluminum doped zinc oxide (AZO), and adjacent layers may include different materials.

It is illustrated that the first to third light-emitting elements LD1, LD2, and LD3 respectively have the first to third resonance distances RD1, RD2, and RD3, but some respective light-emitting elements may have the same resonance distance so as to increase process efficiency. For example, the first and second light-emitting elements LD1 and LD2 may be configured to have the same resonance distance, or the second and third light-emitting elements LD2 and LD3 may be configured to have the same resonance distance.

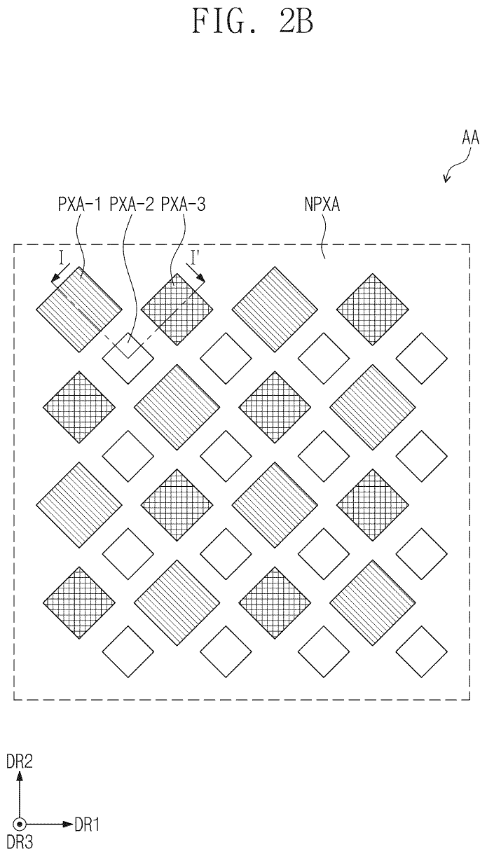

FIGS. 4 to 11 are cross-sectional views illustrating a method of manufacturing a display panel DP according to one or more embodiments of the present disclosure. Hereinafter, a detailed description of components that are the same as the components described with reference to FIG. 2C will be omitted.

As illustrated in FIG. 4, a sixth insulation layer 60 is formed. Components located under the sixth insulation layer 60 may be the same as those described with reference to FIG. 2C, and a manufacturing process thereof may be performed through a manufacturing process for a display panel.

Meanwhile, the contact hole CNT1 that has been described with reference to FIG. 2C is formed in the sixth insulation layer 60. After forming the sixth insulation layer 60, the contact hole CNT1 may be formed by exposing the sixth insulation layer 60 using a mask and developing the sixth insulation layer 60. Hereinafter, the three contact holes CNT1 illustrated in FIG. 2C are not provided for convenience of explanation.

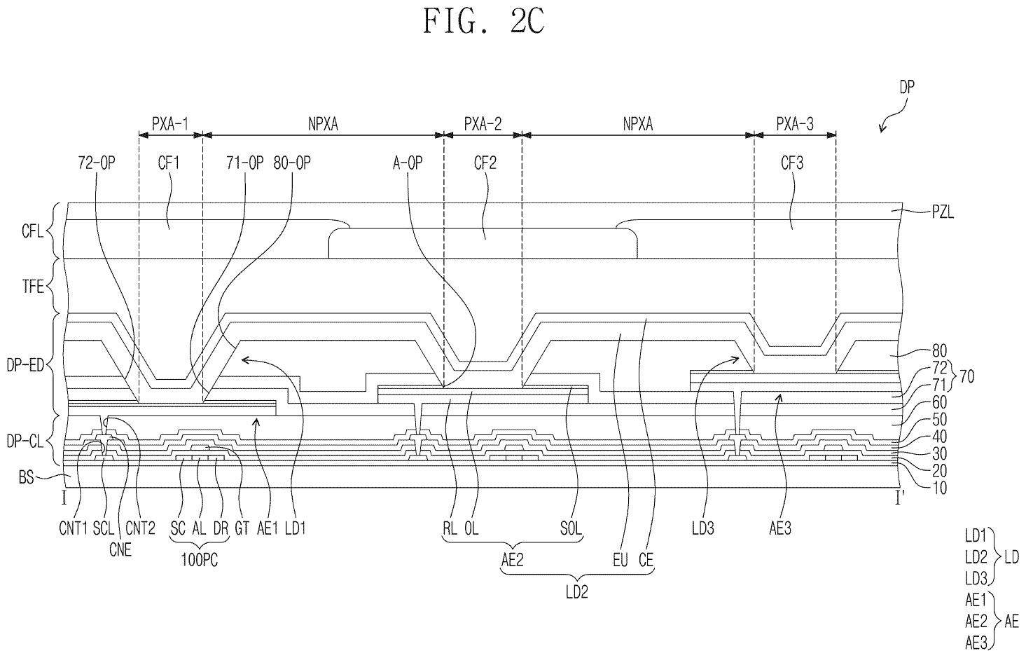

As illustrated in FIG. 5, a (1-1)-th electrode AE1 is formed on the sixth insulation layer 60. A reflection layer RL, a metal oxide layer OL, and an auxiliary metal oxide layer SOL are sequentially formed on the sixth insulation layer 60. After forming a photoresist layer on the auxiliary metal oxide layer SOL, the reflection layer RL, the metal oxide layer OL, and the auxiliary metal oxide layer SOL are patterned through exposure, development, and etching processes. The photoresist layer is then removed.

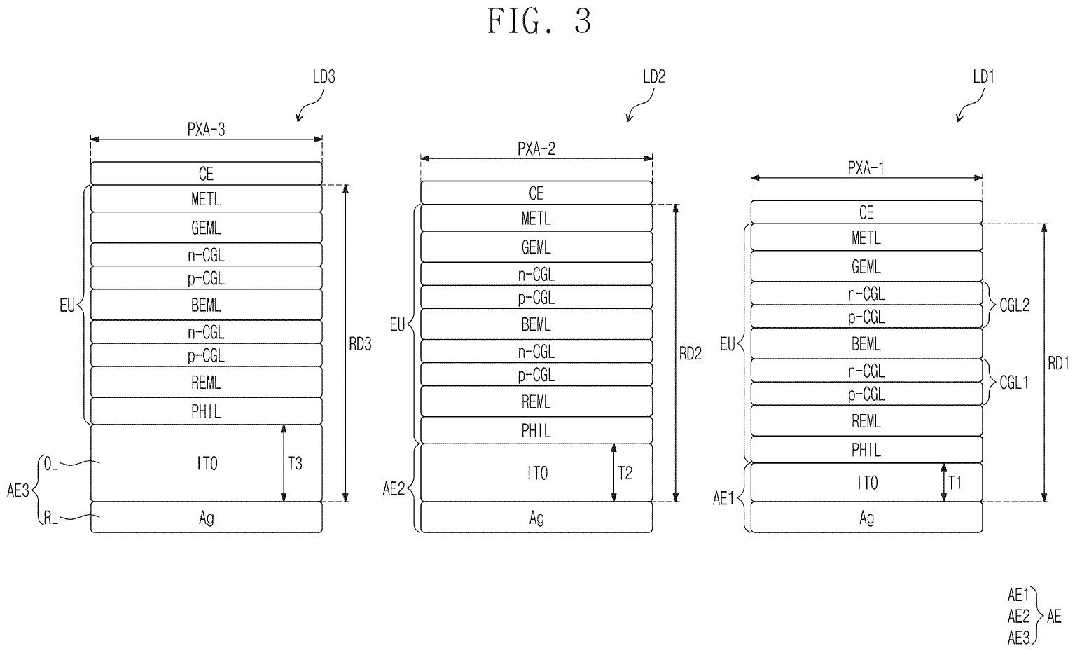

Next, as illustrated in FIG. 6, a first inorganic layer 71 covering the (1-1)-th electrode AE1 is formed on the sixth insulation layer 60. The first inorganic layer 71 may be formed through a deposition process.

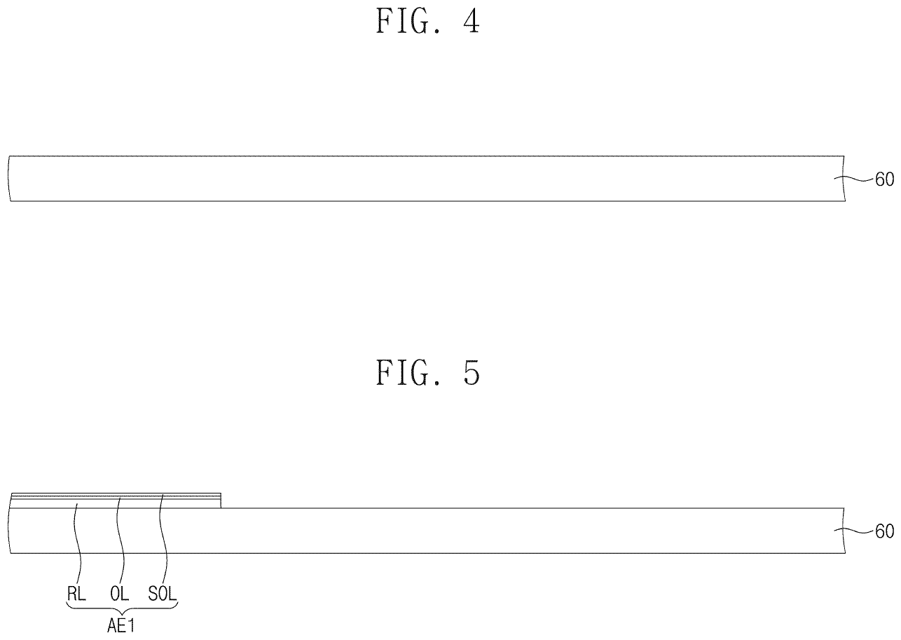

Then, as illustrated in FIG. 7, a (1-2)-th electrode AE2 is formed on the first inorganic layer 71. The (1-2)-th electrode AE2 may be formed through a similar method to the (1-1)-th electrode AE1. However, the cycle or time for a deposition process may be increased so as to form a relatively thicker metal oxide layer OL. Here, the first inorganic layer 71 may protect the (1-1)-th electrode AE1 from a wet etching process.

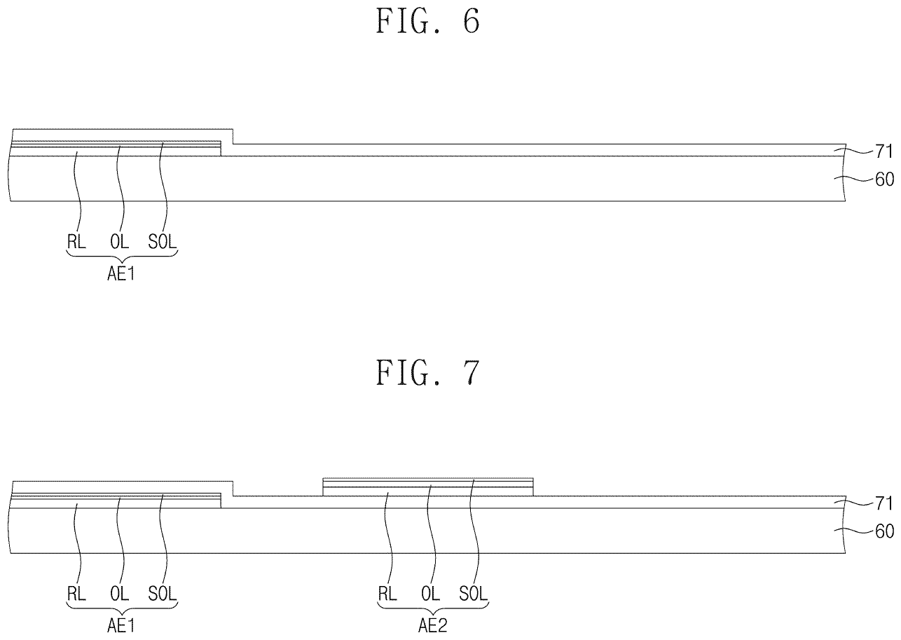

Subsequently, as illustrated in FIG. 8, a second inorganic layer 72 covering the (1-2)-th electrode AE2 is formed on the first inorganic layer 71. The second inorganic layer 72 may be formed through a deposition process. The second inorganic layer 72 may also include the same material as the first inorganic layer 71.

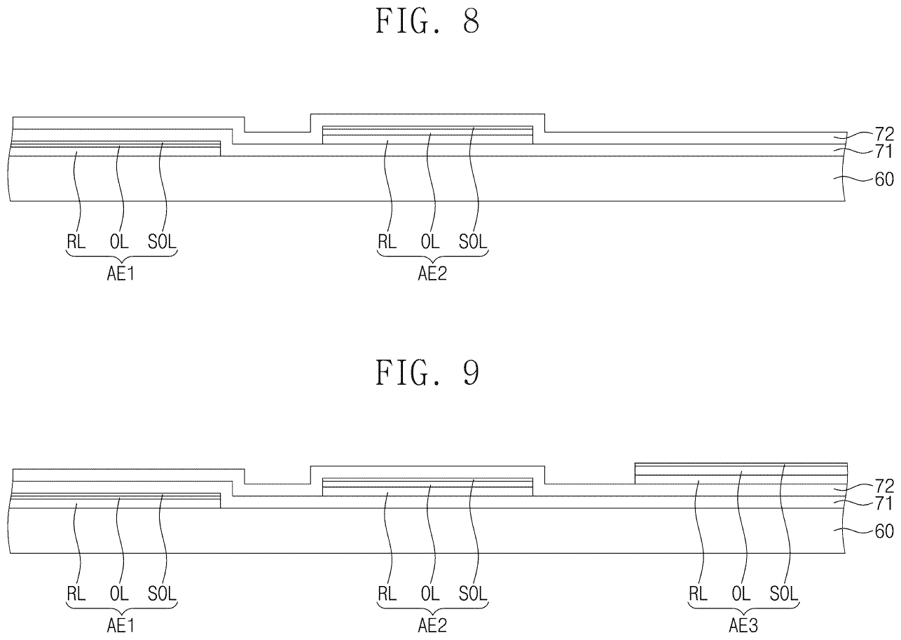

Thereafter, as illustrated in FIG. 9, a (1-3)-th electrode AE3 is formed on the second inorganic layer 72. The (1-3)-th electrode AE3 may be formed through a similar method to the (1-1)-th electrode AE1. Here, the second inorganic layer 72 may protect the (1-2)-th electrode AE2 from a wet etching process.

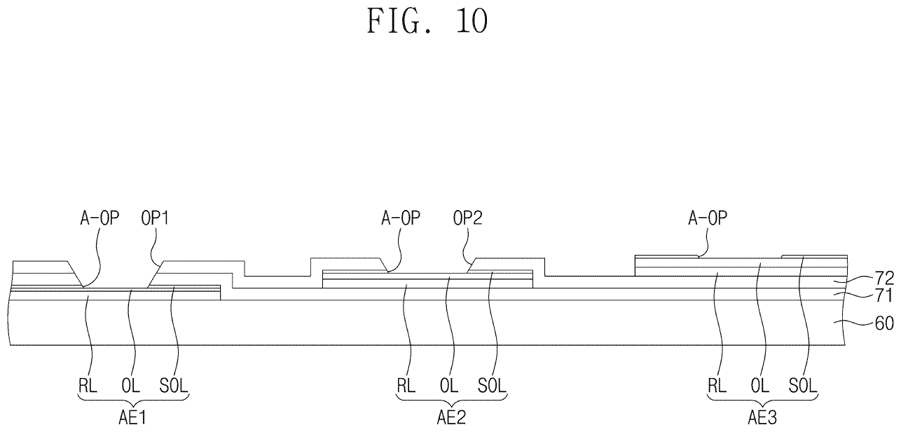

Afterwards, as illustrated in FIG. 10, openings OP1 and OP2 are respectively formed in the first inorganic layer 71 and the second inorganic layer 72. The openings OP1 and OP2 are formed such that the (1-1)-th electrode AE1 and the (1-2)-th electrode AE2 are respectively exposed from the first inorganic layer 71 and the second inorganic layer 72. A dry etching process may be performed.

The opening OP1 is formed in the first inorganic layer 71 and the second inorganic layer 72 to correspond to the (1-1)-th electrode AE1, and in this case, the auxiliary metal oxide layer SOL protects the metal oxide layer OL thereunder. In this process, an opening A-OP corresponding to the opening OP1 of the first inorganic layer 71 and the second inorganic layer 72 is also formed in the auxiliary metal oxide layer SOL.

The opening OP2 is formed in the second inorganic layer 72 to correspond to the (1-2)-th electrode AE2, and in this case, the auxiliary metal oxide layer SOL protects the metal oxide layer OL thereunder. An opening A-OP corresponding to the opening OP2 of the second inorganic layer 72 is also formed in the auxiliary metal oxide layer SOL. An opening A-OP is also formed in the auxiliary metal oxide layer SOL of the (1-3)-th electrode AE3.

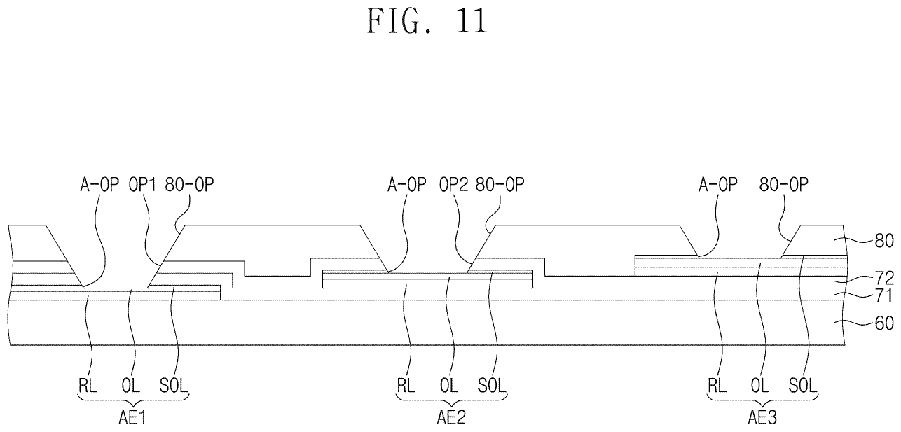

Thereafter, as illustrated in FIG. 11, a pixel-defining film 80 is formed on the second inorganic layer 72. An organic layer is formed to overlap the (1-1)-th electrode AE1, the (1-2)-th electrode AE2, and the (1-3)-th electrode AE3. Then, openings 80-OP may be formed in the pixel-defining film 80 through exposure and development processes.

In one or more embodiments, afterwards, a formation process of an emission unit EU and a formation process of a second electrode CE, which have been described with reference to FIG. 2C, may be performed. In addition, a thin-film encapsulation layer TFE may be formed, and a color filter layer CFL may be formed. Such an additional manufacturing process may be performed through a typical manufacturing process for a display panel.

According to the above, a resonance distance may be controlled by adjusting a thickness of a first electrode of a light-emitting element. Emission efficiency of target light among first to third color light generated from respective emission units may be increased by varying thicknesses of the first electrodes of first to third light-emitting elements.

A first inorganic layer and a second inorganic layer may protect the first electrode from a dry etching process performed during a manufacturing process.

In the above, description has been made with reference to embodiments, but those skilled in the art or those of ordinary skill in the relevant technical field may understand that various modifications and changes may be made to the present disclosure within the scope not departing from the spirit and the technology scope of the present disclosure described in the claims.

Therefore, the technical scope of the present disclosure is not limited to the contents described in the detailed description of the specification, but should be determined by the claims, with functional equivalents thereof to be included therein.

What is claimed is:

1. A display panel comprising:
a first light-emitting element comprising:
a (1-1)-th electrode comprising a reflection layer, and a metal oxide layer above the reflection layer;
a first emission unit above the (1-1)-th electrode and configured to generate first color light, second color light, and third color light; and
a (2-1)-th electrode above the first emission unit; and
a second light-emitting element comprising:
a (1-2)-th electrode comprising a reflection layer, and a metal oxide layer above the reflection layer and that is thicker than the metal oxide layer of the (1-1)-th electrode;
a second emission unit above the (1-2)-th electrode and configured to generate the first color light, the second color light, and the third color light; and
a (2-2)-th electrode above the second emission unit,
wherein a difference between a distance from an upper surface of the reflection layer of the (1-1)-th electrode to a lower surface of the (2-1)-th electrode and a distance from an upper surface of the reflection layer of the (1-2)-th electrode to a lower surface of the (2-2)-th electrode is substantially equal to a difference between a thickness of the metal oxide layer of the (1-1)-th electrode and a thickness of the metal oxide layer of the (1-2)-th electrode.

2. The display panel of claim 1, wherein the first emission unit and the second emission unit are integrated and have a same stacked structure.

3. The display panel of claim 2, wherein the first emission unit comprises:
a first emission layer configured to generate the third color light;
a first charge generation layer above the first emission layer;
a second emission layer above the first charge generation layer, and configured to generate the first color light;
a second charge generation layer above the second emission layer; and
a third emission layer above the second charge generation layer, and configured to generate the second color light.

4. The display panel of claim 1, further comprising:
a third light-emitting element comprising a (1-3)-th electrode comprising a reflection layer and a metal oxide layer above the reflection layer and that is thicker than the metal oxide layer of the (1-2)-th electrode;
a third emission unit above the (1-3)-th electrode and configured to generate the first color light, the second color light, and the third color light; and
a (2-3)-th electrode above the third emission unit,
wherein a difference between a distance from an upper surface of the reflection layer of the (1-2)-th electrode to a lower surface of the (2-2)-th electrode and a distance from an upper surface of the reflection layer of the (1-3)-th electrode to a lower surface of the (2-3)-th electrode is substantially equal to a difference between the thickness of the metal oxide layer of the (1-2)-th electrode and a thickness of the metal oxide layer of the (1-3)-th electrode.

5. The display panel of claim 1 wherein the (1-1)-th electrode further comprises an auxiliary metal oxide layer above the metal oxide layer, and defining an opening.

6. The display panel of claim 1, further comprising:
a base insulation layer under the (1-1)-th electrode, and contacting the (1-1)-th electrode; and
a first inorganic layer above the base insulation layer, and defining a first opening overlapping the (1-1)-th electrode and exposing the (1-1)-th electrode.

7. The display panel of claim 6, wherein the (1-2)-th electrode is above the first inorganic layer and contacts the first inorganic layer.

8. The display panel of claim 6, further comprising a second inorganic layer above the first inorganic layer, defining a first opening overlapping the (1-1)-th electrode and corresponding to the first opening of the first inorganic layer, and defining a second opening overlapping the (1-2)-th electrode and exposing the (1-2)-th electrode are defined.

9. The display panel of claim 8, further comprising an organic layer above the second inorganic layer, defining a first opening corresponding to the first opening of the second inorganic layer, and defining a second opening corresponding to the second opening of the second inorganic layer.

10. The display panel of claim 1, further comprising:
a thin-film encapsulation layer covering the first light-emitting element and the second light-emitting element;
a first color filter above the thin-film encapsulation layer and overlapping the first light-emitting element; and
a second color filter above the thin-film encapsulation layer and overlapping the second light-emitting element.

11. A method of manufacturing a display panel, the method comprising:
forming, above a base insulation layer, a (1-1)-th electrode comprising a reflection layer, and a metal oxide layer above the reflection layer;
forming a first inorganic layer covering the (1-1)-th electrode;
forming, above the first inorganic layer, a (1-2)-th electrode comprising a reflection layer, and a metal oxide layer above the reflection layer that is thicker than the metal oxide layer of the (1-1)-th electrode;
forming a second inorganic layer covering the (1-2)-th electrode;
forming, in the first inorganic layer and the second inorganic layer, a first opening exposing the (1-1)-th electrode;
forming, in the second inorganic layer, a second opening exposing the (1-2)-th electrode;
forming, above the (1-1)-th electrode and the (1-2)-th electrode, an emission unit configurated to generate first color light, second color light, and third color light; and
forming a second electrode above the emission unit.

12. The method of claim 11, wherein a difference between a distance from an upper surface of the reflection layer of the (1-1)-th electrode to a lower surface of the second electrode and a distance from an upper surface of the reflection layer of the (1-2)-th electrode to the lower surface of the second electrode is substantially equal to a difference between a thickness of the metal oxide layer of the (1-1)-th electrode and a thickness of the metal oxide layer of the (1-2)-th electrode.

13. The method of claim 11, wherein the (1-1)-th electrode further comprises an auxiliary metal oxide layer above the metal oxide layer, and
wherein forming the first opening comprises forming an opening corresponding to the first opening in the auxiliary metal oxide layer.

14. The method of claim 11, further comprising forming an organic layer above the second inorganic layer,
wherein forming the first opening comprising forming an opening corresponding to the first opening in the organic layer.

15. The method of claim 11, further comprising:
forming a thin-film encapsulation layer above the second electrode; and
forming, above the thin-film encapsulation layer, a first color filter overlapping the (1-1)-th electrode, and a second color filter overlapping the (1-2)-th electrode.

16. An electronic apparatus comprising:
a display panel; and
a processor configured to control a driving of the display panel,
wherein the display panel comprises:
a first light-emitting element comprising:
a (1-1)-th electrode comprising a reflection layer, and a metal oxide layer above the reflection layer;
a first emission unit above the (1-1)-th electrode and configured to generate first color light, second color light, and third color light; and
a (2-1)-th electrode above the first emission unit; and
a second light-emitting element comprising:
a (1-2)-th electrode comprising a reflection layer, and a metal oxide layer above the reflection layer and that is thicker than the metal oxide layer of the (1-1)-th electrode;
a second emission unit above the (1-2)-th electrode and configured to generate the first color light, the second color light, and the third color light; and
a (2-2)-th electrode above the second emission unit, and
wherein a difference between a distance from an upper surface of the reflection layer of the (1-1)-th electrode to a lower surface of the (2-1)-th electrode and a distance from an upper surface of the reflection layer of the (1-2)-th electrode to a lower surface of the (2-2)-th electrode is substantially equal to a difference between a thickness of the metal oxide layer of the (1-1)-th electrode and a thickness of the metal oxide layer of the (1-2)-th electrode.

17. The electronic apparatus of claim 16, further comprising a frame accommodating the display panel, and a lens accommodated inside the frame and overlapping the display panel.

18. The electronic apparatus of claim 16, wherein the electronic apparatus comprises a virtual reality headset.

19. The electronic apparatus of claim 16, wherein the first emission unit and the second emission unit are integrated and have a same stacked structure.

20. The electronic apparatus of claim 16, wherein the (1-1)-th electrode further comprises an auxiliary metal oxide layer above the metal oxide layer and defining an opening.
